(19) United States
(12) Patent Application Publication
(10) Pub. No.: US 2025/0072272 A1
(43) Pub. Date: Feb. 27, 2025

(54) DISPLAY MODULE AND TERMINAL DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Hao SUN, Beijing (CN); Liang GAO, Beijing (CN); Ajuan DU, Beijing (CN); Feifan LI, Beijing (CN); Hufei YANG, Beijing (CN); Yongle WANG, Beijing (CN); Enjian YANG, Beijing (CN); Yilun ZENG, Beijing (CN); Guodong ZENG, Beijing (CN); Yiqian WU, Beijing (CN); Yunhui HUANG, Beijing (CN); Wei CHEN, Beijing (CN); Xiaoxia HUANG, Beijing (CN); Mengyuan PANG, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/847,831

(22) PCT Filed: May 16, 2023
(86) PCT No.: PCT/CN2023/094418

§ 371 Date: Sep. 17, 2024

(30) Foreign Application Priority Data
Jun. 29, 2022 (CN) 202210763571.5

(51) Int. Cl. H10K 77/10; G06F 1/16; H10K 59/131; H10K 59/40; H10K 59/80; H10K 102/00

(52) U.S. Cl. CPC H10K 77/111; G06F 1/1652; H10K 59/131; H10K 59/40; H10K 59/8722; H10K 2102/311

(57) ABSTRACT

A display module includes a display panel and a peripheral region. The peripheral region includes a bendable fan-out region including a panel bonding portion and a driving chip; a flexible circuit board, including a first and a second conductive layers, and a substrate. The first conductive layer includes a first and a second bonding portions, and a connection portion; the second conductive layer is located on a side of the first conductive layer and at least partially overlaps with the first bonding portion; the first and the second conductive layers are connected through a via hole penetrating through the substrate; an end of the flexible circuit board is bonded to the panel bonding portion through the first bonding portion, and the second bonding portion is bonded to a control circuit board; and a conductive protection layer, covering the driving chip and connected to the second conductive layer.

### CROSS REFERENCE TO RELATED APPLICATIONS

The present application is the U.S. national stage of International Application No. PCT/CN2023/094418, filed on May 16, 2023, which claims priority to Chinese Patent Application No. 202210763571.5 entitled “Display module and terminal device”, filed on Jun. 29, 2022, and the entire contents of both of which are incorporated herein by reference for all purposes.

### TECHNICAL FIELD

The present disclosure relates to the field of display technology, and in particular, to a display module and a terminal device.

### BACKGROUND

The display module is an indispensable component in electronic devices such as a mobile phone and a computer, where it is widely applied to use an organic light-emitting diode (OLED) as an OLED display module of the light-emitting device. However, the current display module is prone to occur abnormal display due to interference from static electricity.

It should be noted that the information disclosed in the above background part is only used to enhance the understanding of the background of the present disclosure, and therefore may include information that does not constitute related art known to those of ordinary skill in the art.

### SUMMARY

An objective of the present disclosure is to overcome the shortcomings of the above-mentioned related art, and provide a display module and a terminal device, which can reduce the risk of abnormal display.

According to an aspect of the present disclosure, there is provided a display module, including:
a display panel, provided with a display region and a peripheral region located outside the display region, where the peripheral region includes a bendable fan-out region: the fan-out region is provided with a panel bonding portion, and the fan-out region is provided with a driving chip:
a flexible circuit board, including a first conductive layer, a second conductive layer, and a substrate separated between the first conductive layer and the second conductive layer; where the first conductive layer includes a first bonding portion, a second bonding portion, and a connection portion connecting the first bonding portion and the second bonding portion; the second conductive layer is located on a side of the first conductive layer away from the display panel and at least partially overlaps with the first bonding portion; the first conductive layer and the second conductive layer are connected to each other through a via hole penetrating through the substrate; an end of the flexible circuit board is bonded to the panel bonding portion through the first bonding portion, and the second bonding portion is configured to be bonded to a control circuit board; and
a conductive protection layer, covering the driving chip and connected to the second conductive layer.

In some embodiments of the present disclosure, the flexible circuit board further includes a first protective layer and a second protective layer, the first protective layer covers the first conductive layer and exposes the first bonding portion and the second bonding portion, and the second protective layer covers a partial region of the second conductive layer.

In some embodiments of the present disclosure, the first bonding portion includes a first alignment mark and a plurality of first pads distributed at intervals, and the first pads are bonded to the panel bonding portion: the second conductive layer is provided with a light-transmitting hole, and the light-transmitting hole overlaps with the first alignment mark.

In some embodiments of the present disclosure, a number of the first alignment mark and a number of the light-transmitting hole are both more than one, and a first pad is located between two adjacent first alignment marks: and the light-transmitting hole overlaps with the first alignment mark in one-to-one correspondence.

In some embodiments of the present disclosure, a first alignment mark and a first pad are of an integrated structure.

In some embodiments of the present disclosure, the second conductive layer further overlaps with the connecting portion and the second bonding portion.

In some embodiments of the present disclosure, the second conductive layer is of a mesh structure.

In some embodiments of the present disclosure, the second conductive layer only overlaps with the first bonding portion.

In some embodiments of the present disclosure, materials of the first conductive layer and the second conductive layer are the same.

In some embodiments of the present disclosure, a boundary of the conductive protection layer is located within a boundary of the display panel.

In some embodiments of the present disclosure, the conductive protective layer includes an insulating layer and a conductor layer stacked along a direction away from the display panel, the insulating layer covers the driving chip and is attached to the display panel; a partial region of the conductor layer extends to a side of the second conductive layer away from the substrate and is connected to a partial region of the second conductive layer.

In some embodiments of the present disclosure, the display panel includes:
a driving backplane, including the fan-out region and a pixel circuit located within the display region;
a light-emitting device, provided on a side of the driving backplane and located in the display region;
an encapsulation layer, covering the light-emitting device and exposing the driving chip and the panel bonding portion;
a touch layer, provided on a side of the encapsulation layer away from the driving backplane;
an anti-reflection layer, provided on a side of the touch layer away from the driving backplane; and
a transparent cover plate, provided on a side of the anti-reflection layer away from the driving backplane, where a boundary of the driving backplane is located within a boundary of the transparent cover plate.

In some embodiments of the present disclosure, the driving backplane includes a plurality of data lines extending along a column direction and distributed along a row direction, and a data line is connected to at least one column of pixel circuits; and, at least a part of the data lines are connected to the driving chip.

In some embodiments of the present disclosure, the display panel further includes:
a supporting layer, provided on a side of the driving backplane away from the light-emitting device, and including an adhesive layer, a buffer layer, and a metal layer sequentially stacked along a direction away from the driving backplane.

According to an aspect of the present disclosure, there is provided a terminal device, including:
a control circuit board, provided on a backlight side of the display panel; and the display module according to any one of the above, where the second bonding portion is connected to the control circuit board.

According to the display module and the terminal device of the present disclosure, the connection between the control circuit board and the display panel can be realized through the first conductive layer of the flexible circuit board, so as to realize the display function. Meanwhile, since the flexible circuit board further includes a second conductive layer connected to the first conductive layer, and the conductive protection layer covering the driving chip is connected to the second conductive layer, the static electricity affecting the driving chip can be conducted to the control circuit board along the path of the conductive protection layer-the second conductive layer-the first conductive layer, so that the static electricity influence can be eliminated by controlling the circuit board to be grounded, and the normal operation of the driving chip can be ensured. Meanwhile, since the second conductive layer and the first conductive layer play the role of conducting static electricity, the static electricity does not need to be conducted to the control circuit board by relying on the conductive protection layer, and it is only needed to connect the conductive protection layer to the second conductive layer, which is facilitate to reduce the area of the conductive protection layer, preventing the conductive protection layer from causing the panel bonding portion to be stripped from the first bonding portion, thus avoiding the risk of abnormal display.

It is to be understood that both the foregoing general description and the following detailed description are exemplary and explanatory only and are not restrictive of the present disclosure.

### BRIEF DESCRIPTION OF THE DRAWINGS

The accompanying drawings, which are incorporated in and constitute a part of the description, illustrate embodiments consistent with the present disclosure and together with the description serve to explain the principles of the disclosure. Obviously, the drawings in the following description are some embodiments of the present disclosure, and for those of ordinary skill in the art, other drawings can also be obtained from these drawings without creative efforts.

FIG. 1 is a top view of a display panel of a display module according to some embodiments of the present disclosure.

FIG. 2 is a cross-sectional view of a display module according to some embodiments of the present disclosure when a fan-out region is not bent.

FIG. 3 is a cross-sectional view of a display module according to some embodiments of the present disclosure after a fan-out region is bent.

FIG. 4 is a cross-sectional view of a terminal device according to some embodiments of the present disclosure.

FIG. 5 is a cross-sectional view of a display module according to some embodiments of the present disclosure when a fan-out region is not bent.

FIG. 6 is a cross-sectional view of a display module according to some embodiments of the present disclosure after a fan-out region is bent.

FIG. 7 is a cross-sectional view of a terminal device according to some embodiments of the present disclosure.

FIG. 8 is a cross-sectional view of a flexible circuit board of a display module according to some embodiments of the present disclosure.

FIG. 9 is a top view of a first conductive layer in a flexible circuit board of a display module according to some embodiments of the present disclosure.

FIG. 10 is a top view of a second conductive layer in a flexible circuit board of a display module according to some embodiments of the present disclosure.

FIG. 11 is a top view of a second conductive layer in a flexible circuit board of a display module according to some embodiments of the present disclosure.

FIG. 12 is a top view of a second conductive layer in a flexible circuit board of a display module according to some embodiments of the present disclosure.

FIG. 13 is a top view of a display panel and a flexible circuit board according to some embodiments of the present disclosure.

FIG. 14 is a top view of a display module according to some embodiments of the present disclosure.

### DETAILED DESCRIPTION

Example embodiments will now be described more fully with reference to the accompanying drawings. Example embodiments, however, can be implemented in various forms and should not be construed as limited to the embodiments set forth herein; by contrast, these embodiments are provided so that the present disclosure will be thorough and complete, and will fully convey the concept of example embodiments to those skilled in the art. The same reference numerals in the drawings denote the same or similar structures, and thus their detailed descriptions will be omitted. In addition, the drawings are merely schematic illustrations of the present disclosure and are not necessarily drawn to scale.

The terms “a”, “an”, “the”, “said” and “at least one” are used to indicate the presence of one or more elements/components/or the like; the terms “including” and “having” are used to indicate the meaning of an open inclusion and refer to that there may be additional elements/components/or the like in addition to the listed elements/components/or the like; and the terms “first”, “second”, “third”, or the like, are only used as markers, rather than limitation on the number of objects thereof.

The row direction X and the column direction Y here are only two mutually perpendicular directions. In the drawings of the present disclosure, the row direction X may be transverse, and the column direction Y may be longitudinal, but not limited to this. If the display panel rotates, the actual orientations of the row direction X and the column direction Y may change.

“Overlapping” between feature A and feature B here means that the orthographic projection of the feature A on a plane at least partially overlaps with the orthographic projection of the feature B on the plane, the plane is any plane perpendicular to the distribution direction of A and B, and the plane here may be a side surface of the substrate or a surface of the display panel, etc.

In the related art, the display module of a terminal device includes a display panel and a flexible circuit board bonded to the display panel, where the display panel has a display region and a fan-out region outside the display region, and the fan-out region may be bonded to a control circuit board through the flexible circuit board, so that the display panel may be controlled to display an image through the control circuit board. The fan-out region may be provided with a driving chip, the driving chip may be a source driving chip for inputting a data signal to the pixel circuit within the display region, etc., and the functions of the driving chip are not particularly limited here.

When the terminal device is used, if a finger touches terminal device at the driving chip, a lot of static electricity may be generated, and the static electricity generated instantaneously may be up to thousands of volts, resulting in a failure or even damage to the driving chip. Thus, it is necessary to perform static electricity protection for the driving chip.

In order to protect the driving chip, the conductive protection layer may be used to cover the driving chip, and cover the flexible circuit board and the control circuit board simultaneously; therefore, static electricity is conducted to the control circuit board through the conductive protection layer, and the static electricity is grounded. However, when the conductive protective layer is used to cover the driving chip and the flexible circuit board, an acting force may be generated at the bonding position between the flexible circuit board and the display panel, which may cause the flexible circuit board to be stripped from the display panel, resulting in a bonding failure, causing abnormal display or even inability to display. If the area of the conductive protective layer is reduced, it is difficult to achieve grounding, and the influence of static electricity cannot be eliminated.

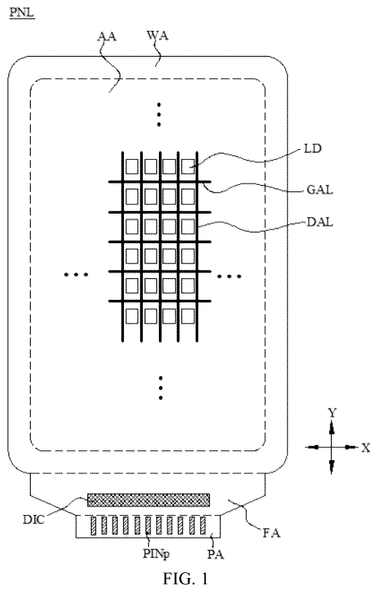

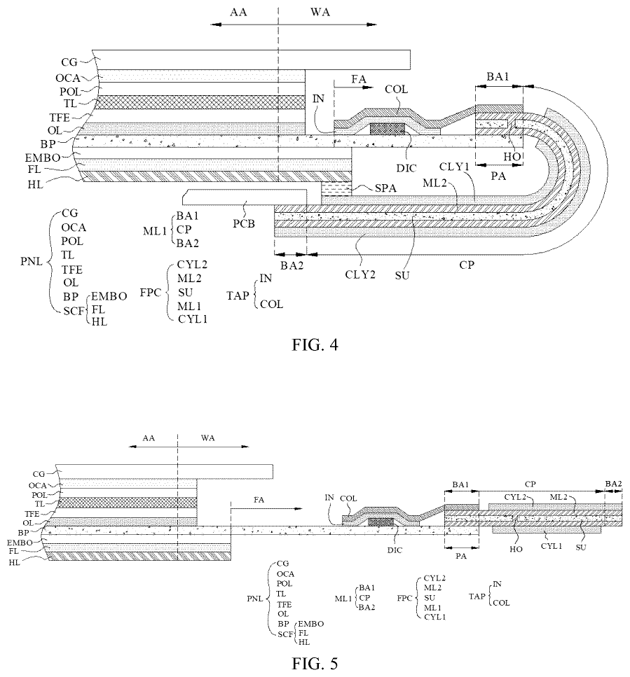

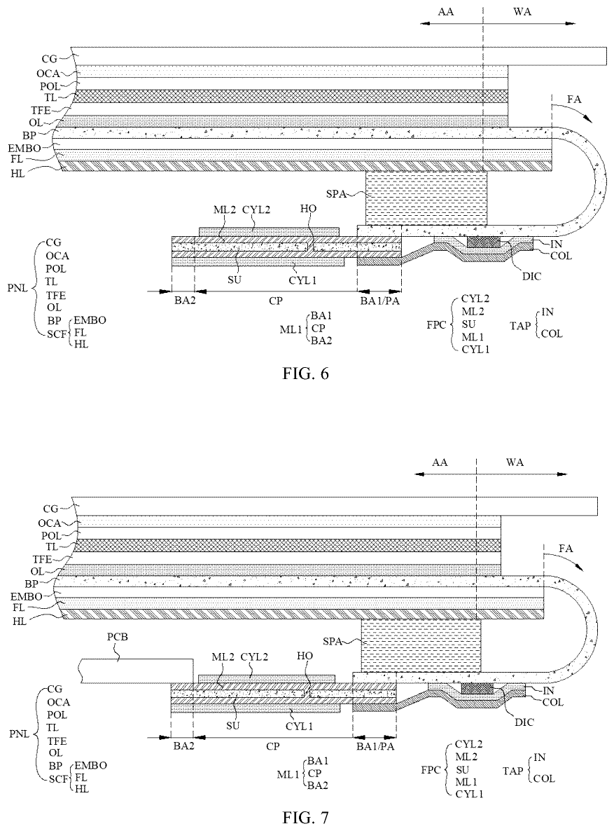

Based on the above-mentioned related art, embodiments of the present disclosure provide a display module. As shown in FIG. 1 to FIG. 7, the display module may include a display panel PNL, a flexible circuit board FPC, and a conductive protective layer TAP.

The display panel PNL has a display region AA and a peripheral region WA located outside the display region AA, and the peripheral region WA includes a bendable fan-out region FA. The fan-out region FA is provided with a driving chip DIC and a panel bonding portion PA.

The flexible circuit board FPC includes a first conductive layer ML1, a second conductive layer ML2, and a substrate separated between the first conductive layer ML1 and the second conductive layer ML2. The first conductive layer ML1 includes a first bonding portion BA1, a second bonding portion BA2, and a connection portion CP connecting the first bonding portion BA1 and the second bonding portion BA2. The second conductive layer ML2 is located on a side of the first conductive layer ML1 away from the display panel PNL and at least partially overlaps with the first bonding portion BA1. The first conductive layer ML1 and the second conductive layer ML2 are connected through a via hole HO penetrating through the substrate. An end of the flexible circuit board FPC is bonded to the panel bonding portion PA through the first bonding portion BA1, and the second bonding portion BA2 is configured to be bonded to the control circuit board PCB.

The conductive protection layer TAP covers the driving chip DIC and is connected to the second conductive layer ML2.

According to the display module of the present disclosure, the connection between the control circuit board PCB and the display panel PNL can be realized through the first conductive layer ML1 of the flexible circuit board FPC, so as to realize the display function. Meanwhile, since the flexible circuit board FPC further includes the second conductive layer ML2 connected to the first conductive layer ML1, and the conductive protection layer TAP covering the driving chip DIC is connected to the second conductive layer ML2, the static electricity affecting the driving chip DIC can be conducted to the control circuit board PCB along the path of the conductive protection layer TAP-the second conductive layer ML2-the first conductive layer ML1, so that the static electricity influence can be eliminated by controlling the circuit board PCB to be grounded, and the normal operation of the driving chip DIC can be ensured. Meanwhile, since the second conductive layer ML2 and the first conductive layer ML1 play the role of conducting static electricity, it is only needed to connect the conductive protective layer TAP to the second conductive layer ML2, which is facilitate to reduce the area of the conductive protective layer TAP, preventing the conductive protective layer TAP from causing the panel bonding portion PA to be stripped from the first bonding portion BA1, thus avoiding the risk of abnormal display.

Each part of the display module of the present disclosure will be described in detail below.

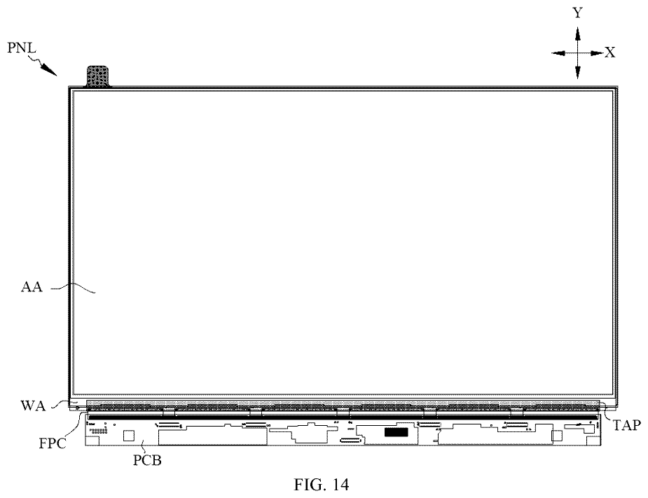

As shown in FIG. 1, the display panel PNL may have a display region AA and a peripheral region WA located outside the display region AA. The display region AA may emit light to image, the peripheral region WA may be used for setting of circuits and wirings, and the peripheral region WA may include a fan-out region FA. The driving chip DIC is provided within the fan-out region FA, and may be a source driving chip DIC, etc., which is not specifically limited here. The number of the driving chip DIC may be one or more. The fan-out region FA may include a panel bonding portion PA, the panel bonding portion PA may be provided on a side of the driving chip DIC away from the display region AA, and the panel bonding portion PA may include a plurality of panel pads PINp for bonding to the flexible circuit board FPC. Each panel pad PINp may be distributed at intervals along the row direction X. The number of the fan-out region FA may be one, two or more, and each fan-out region FA may be bonded to a flexible circuit board FPC, that is, to be electrically connected. For example, as shown in FIG. 1, for a terminal device that can be hand-held, such as a mobile phone, the display panel PNL may have only one fan-out region FA. As shown in FIG. 13 and FIG. 14, for a terminal device such as a television or a notebook computer, the display panel PNL may have a plurality of fan-out regions FA, each fan-out region FA may be bonded to a flexible circuit board FPC, and each flexible circuit board FPC may be bonded to the same control circuit board PCB.

Meanwhile, the display panel PNL may be a hard panel, which cannot be bent, and it is needed to bend the flexible circuit board FPC to the backlight side so as to be bonded to the control circuit board PCB. Alternatively, the display panel PNL may be a flexible panel, so that the fan-out region FA may be bent towards the backlight side of the display panel PNL, which is beneficial to narrowing the frame. In some embodiments, for the flexible panel, bending may not be performed on the flexible panel, but the flexible circuit board FPC may be bent to the backlight side, and may also be bonded to the control circuit board PCB.

In some embodiments of the present disclosure, the display panel PNL may be an organic electroluminescent display panel PNL, which may include a driving backplane BP, a light-emitting device layer OL, and an encapsulation layer TFE.

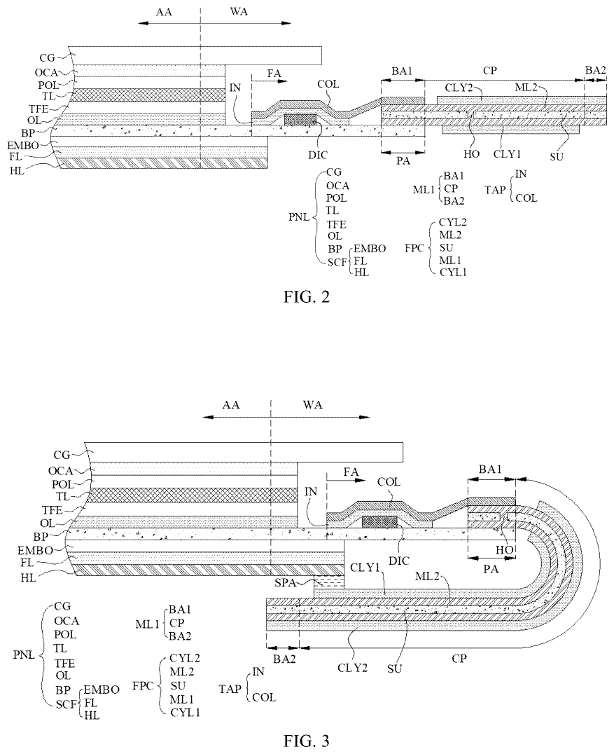

As shown in FIG. 1 and FIG. 2, the driving backplane BP has a driving circuit, and the driving circuit may drive a plurality of light-emitting devices of the light-emitting device layer OL to emit light, so as to display an image, where, the driving backplane BP may include a substrate and a circuit layer located on a side of the substrate. The substrate may be of a flat plate structure. The material of the substrate may be a hard material such as glass, or may be a soft material such as polyimide (PI) and polyethylene terephthalate (PET). Meanwhile, the substrate may be of a single-layer or multi-layer structure. For the flexible display panel PNL, the substrate may be a bendable substrate made of a soft material such as polyimide.

It should be noted that “hard” here means that recoverable bending cannot be performed, and “soft” means that recoverable bending may be performed, that is, it can be repeatedly bent for a plurality of times.

As shown in FIG. 1, the circuit layer may include a driving circuit, and the driving circuit may drive the light-emitting device to emit light. The driving circuit may include a pixel circuit located within the display region AA and a peripheral circuit located within the peripheral region WA, where the pixel circuit may be a pixel circuit such as 7T1C and 6T1C, as long as the pixel circuit can drive the light-emitting device to emit light. The structure of the pixel circuit is not specifically limited here. The number of the pixel circuit may be the same as the number of the light-emitting device, and the pixel circuit is connected to each light-emitting device in one-to-one correspondence, so as to control each light-emitting device to emit light respectively. Among them, nTmC indicates that a pixel circuit includes N transistors (denoted by the letter “T”) and M capacitors (denoted by the letter “C”). In some embodiments, the same pixel circuit may also be connected to a plurality of light-emitting devices, and drive the plurality of light-emitting devices to emit light simultaneously, which is not specifically limited here.

The peripheral circuit is connected to the pixel circuit, and is configured to input a driving signal to the pixel circuit to control the light-emitting device to emit light. The peripheral circuit may include a gate driving circuit and a light-emitting control circuit, and In some embodiments, may further include other circuits. The specific structure of the peripheral circuit is not specifically limited here.

For example, on one hand, the peripheral circuit may be connected to the light-emitting device through the pixel circuit to apply a first power signal to the first electrode of the light-emitting device: and on the other hand, the peripheral circuit may also be connected to the second electrode CAT of the light-emitting device and apply a second power signal to the second electrode CAT. By controlling the pixel circuit, the peripheral circuit may control the current passing through the light-emitting device LD, thus controlling the brightness of the light-emitting device.

Furthermore, in order to facilitate the transmission of signals, the driving backplane BP may also have a plurality of signal lines extending along the row direction X. The signal lines extending along the row direction X may be distributed along the column direction Y, and at least include scan lines GAL for controlling the transistors to be turned on or turned off. The same scan line GAL may be connected to at least one row of pixel circuits. Meanwhile, the driving backplane BP may further include a plurality of signal lines extending along the column direction Y. The signal lines extending along the column direction Y are distributed along the row direction X, and include at least power lines and data lines DAL. A column of pixel circuits may be connected to a power line and a data line DAL, the power line may be used to transmit a first power signal, and the data line DAL may be used to transmit a data signal. The pixel circuit may control the current passing through the light-emitting device according to the size of the data signal. At least a part of the data lines DAL may be connected to a driving chip DIC, and the driving chip DIC may be used to output a data signal. In this case, the driving chip DIC is a source driving signal. The detailed working principle of the pixel circuit is not described in detail here.

The above-mentioned circuit layer may include a plurality of thin film transistors and a capacitor, where the thin film transistor may be a top gate thin film transistor or a bottom gate thin film transistor. Each thin film transistor may include an active layer and a gate, a channel of each thin film transistor may be located on a same semiconductor layer, and the gate may be provided on a same gate layer to simplify the process. Taking the top gate thin film transistor as an example, the circuit layer may include a semiconductor layer, a first gate insulating layer, a first gate layer, a second gate insulating layer, a second gate layer, an interlayer dielectric layer, a first source-drain layer, a passivation layer, a first planarization layer, a second source-drain layer, and a second planarization layer that are sequentially stacked along a direction away from the substrate. The channel of each transistor may be located on the semiconductor layer, at least a part of the scanning lines and the first plate of the capacitor may be located on the first gate layer, and the second plate of the capacitor may be located on the second gate layer. The power line and the data line DAL may be located on the second source-drain layer. The specific pattern of each film layer depends on the specific composition of the driving circuit, which is not specifically limited here.

As shown in FIG. 1, the light-emitting device layer OL may be provided on a side of the driving backplane BP, for example, the light-emitting device is provided on a surface of the second planarization layer away from the substrate. The light-emitting device layer OL may include a plurality of light-emitting devices distributed in an array, and the light-emitting device may be located within a range of the display region AA. The light-emitting device may be an organic light-emitting diode, and may include a first electrode, a light-emitting functional layer, and a second electrode sequentially stacked along a direction away from the driving backplane BP.

The first electrode may be provided on a side of the second planarization layer away from the substrate and connected to a pixel circuit. The light-emitting functional layer may include a hole injection layer, a hole transport layer, a composite light-emitting layer, an electron transport layer, and an electron injection layer that are sequentially stacked along a direction away from the driving backplane BP. The second electrode may cover the light-emitting functional layer and extend to the peripheral region WA, for receiving the second power signal. The specific principle of light emission of the organic light-emitting diode is not described in detail here.

As shown in FIG. 1, in order to define the range of each light-emitting device easily and reduce cross color, the display panel PNL may further include a pixel definition layer. The pixel definition layer and the first electrode may be provided on a surface of the circuit layer away from the substrate, and the pixel definition layer may be provided with a plurality of openings exposing the first electrodes in one-to-one correspondence. The light-emitting function layer is stacked on a region of the first electrode located within the opening. The light-emitting functional layer of each light-emitting device is separated from each other at intervals. The light-emitting colors of different light-emitting functional layers may be the same or different. The second electrode covers the light-emitting functional layer, so that each light-emitting device may share the same second electrode. Each light-emitting device may be defined by the plurality of openings above, and the boundary of any light-emitting device is a boundary of the light-emitting functional layer within the opening corresponding to the light-emitting device.

Of course, in some other embodiments of the present disclosure, the light-emitting functional layer of each light-emitting device may belong to the same continuous light-emitting film layer. The light-emitting film layer covers the surface of each first electrode and pixel definition layer away from the substrate simultaneously. The region of the light-emitting film layer located within the opening and stacked on the first electrode is the light-emitting functional layer of the light-emitting device, and two adjacent light-emitting functional layers are connected to each other through another region of the light-emitting film layer. That is, each light-emitting device may share the light-emitting film layer.

The encapsulation layer TFE may cover the light-emitting device, protect the light-emitting device, and prevent external water and oxygen from corroding the light-emitting device. Meanwhile, the boundary of the encapsulation layer TFE may extend into the peripheral region WA, but expose the driving chip DIC and the panel bonding portion PA. For example, the encapsulation layer TFE may expose the fan-out region FA.

In some embodiments of the present disclosure, the encapsulation may be implemented in a thin-film encapsulation (TFE) manner. The encapsulation layer TFE may include a first inorganic layer, an organic layer, and a second inorganic layer. The first inorganic layer covers the light-emitting device. The organic layer may be provided on a surface of the first inorganic layer away from the driving backplane BP, and a boundary of the organic layer is defined within the inner side of a boundary of the first inorganic layer. The second inorganic layer covers the organic layer and the first inorganic layer not covered by the organic layer. Water and oxygen invasion may be blocked by the second inorganic layer, and planarization may be achieved through the flexible organic layer.

In addition, the display panel PNL of the present disclosure may further include a transparent cover plate CG, which may be provided on a side of the encapsulation layer TFE away from the driving backplane BP. The transparent cover plate CG may be made of transparent materials such as glass or acrylic, so as to play a protection role. A user may touch on the surface of the transparent cover plate CG away from the driving backplane BP.

The display panel PNL of the present disclosure may further include a touch layer TL and an anti-reflection layer POL. The touch layer TL may be provided on a side of the encapsulation layer TFE away from the driving backplane BP, and the transparent cover plate CG is located on a side of the touch layer TL away from the driving backplane BP. The touch layer TL may be of self-capacitive or mutual-capacitive touch structure. For example, the touch layer TL may adopt an add-on manner, or may adopt an on-cell manner such as FMLOC (Flexible Multi-Layer On Cell). The specific structure of the touch layer TL is not specifically limited here, as long as the touch function can be implemented. The user may operate on the side of the transparent cover plate CG away from the driving backplane BP, and the touch position may be sensed through the touch layer TL, so as to implement interaction.

The anti-reflection layer POL may be provided on a side of the touch layer TL away from the driving backplane BP, and configured to absorb ambient light reflected from the inner side of the display panel PNL, which may be a circular polarizer. Alternatively, the anti-reflection layer POL may also be a color film layer formed by a filtering material, the color film layer may have a filtering portion in one-to-one correspondence with each light-emitting device LD. Each light-emitting device emits light independently, and the colors of different light-emitting devices LD may be different (not sharing the light-emitting functional layer). The color of a filtering portion may be the same as the light-emitting color of the light-emitting device corresponding to filtering portion, and the ambient light entering into the display panel PNL may be reduced by the filtering portion, thus reducing the reflection effect on the ambient light.

The transparent cover plate CG may be provided on a side of the anti-reflection layer POL away from the driving backplane BP, and may be adhered to the anti-reflection layer POL through an optical adhesive layer OCA.

The display panel PNL of the present disclosure may further include a supporting layer SCF, which may be provided on a side of the driving backplane BP away from the light-emitting device layer OL. For example, the supporting layer SCF may be provided on a side of the substrate away from the light-emitting device layer OL. The supporting layer SCF may include an adhesive layer EMBO, a buffer layer FL, and a metal layer HL that are sequentially stacked along a direction away from the driving backplane BP, where the adhesive layer EMBO may be a mesh adhesive, and the buffer layer FL may be made of a flexible material such as foam, which may achieve a buffering effect of absorbing stress. The material of the metal layer HL may be a single metal, or may be an alloy. For example, the material of the metal layer HL may be copper or stainless steel (SUS) or the like, which may play a role in improving the strength and heat dissipation of the display panel PNL. In addition, a back film made of an insulating material may be further provided on a side of the driving backplane BP away from the light-emitting device layer OL, and the supporting layer SCF may be provided on a side of the back film away from the driving backplane BP. The fan-out region FA of the display panel PNL is located on the driving backplane BP. The touch layer TL, the anti-reflection layer POL, and the optical adhesive may all be located outside the fan-out region FA.

The boundaries of the light-emitting device layer OL, the encapsulation layer TFE, the touch layer TL, the anti-reflection layer POL and the supporting layer SCF do not exceed the boundary of the driving backplane BP, and the boundary of the driving backplane BP is located within the boundary of the transparent cover plate CG, so that the entire display panel PNL can be protected by the transparent cover plate CG.

As shown in FIG. 8 to FIG. 12, the flexible circuit board FPC may be of a multilayer structure having at least two conductive layers. For example, the flexible circuit board FPC may include a substrate SU, a first conductive layer ML1, and a second conductive layer ML2.

The first conductive layer ML1 may be stacked on a side of the substrate SU, and the second conductive layer ML2 may be stacked on the other side of the substrate SU, so that the first conductive layer ML1 and the second conductive layer ML2 may be separated by the substrate SU. The first conductive layer ML1 and the second conductive layer ML2 may both be made of a conductive material; and, the material may be copper, molybdenum, etc., as long as it can conduct electricity, which is no specially limited here. Furthermore, in order to make the conductivity of the first conductive layer ML1 and the second conductive layer ML2 uniform, and the first conductive layer ML1 and the second conductive layer ML2 may be manufactured by the same process, the materials of the first conductive layer ML1 and the second conductive layer ML2 may be the same; for example, both the materials of the first conductive layer ML1 and the second conductive layer ML2 are copper.

The first conductive layer ML1 includes a first bonding portion BA1, a second bonding portion BA2, and a connection portion CP. The connection portion CP connects the first bonding portion BA1 to the second bonding portion BA2.

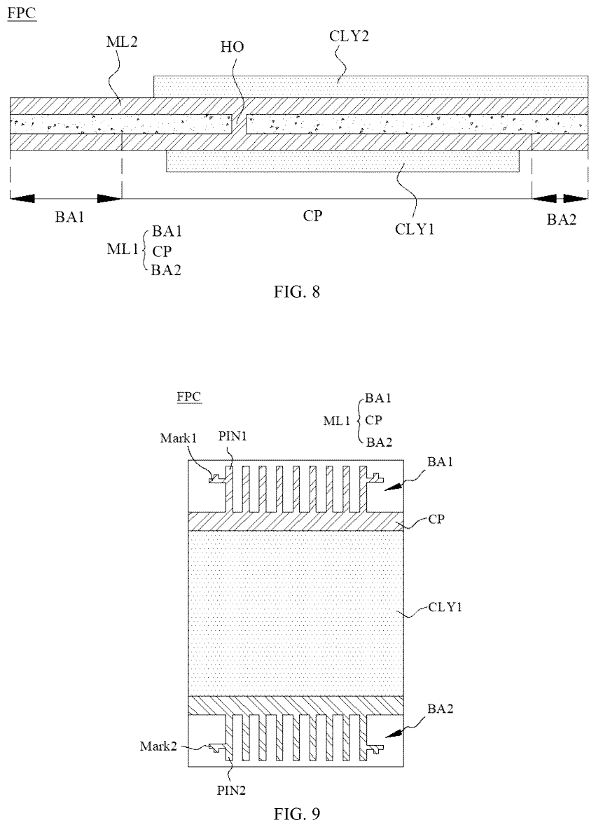

As shown in FIG. 1, the first bonding portion BA1 may be configured to be bonded to the panel bonding portion PA of the display panel PNL, and may include a plurality of first pads PIN1, and the first pad PIN1 may be bonded to the panel pad PINp in one-to-one correspondence to implement electrical connection. After the first pad PIN1 and the panel pad PINp is bonded to each other, the first pad PIN1 may be distributed at intervals along the row direction X. At the same time, as shown in FIG. 9, in order to facilitate alignment at the bonding timing, the first bonding portion BA1 may further include a plurality of first alignment marks MARK1, the shape of which may be a “T” shape, a “+” shape, etc. which is not specifically limited here.

As shown in FIG. 9, a first alignment mark Mark1 and a first pad PIN1 may be of an integrated structure, so that the first alignment mark Mark1 and the first pad PIN1 may be formed simultaneously, which is beneficial to reducing the area required to be etched and reducing the process difficulty.

As shown in FIG. 9, in some embodiments of the present disclosure, there may be two first alignment marks Mark1, and each first pad PIN1 is located between the two first alignment marks Mark1, and the two first alignment marks Mark1 are of integrated structures with the outermost two first pads PIN1, respectively. At the same time, the two first alignment marks Mark 1 may be symmetrically distributed.

As shown in FIG. 9, the second bonding portion BA2 may be configured to be bonded to the control circuit board PCB, and may include a plurality of second pads PIN2, which may be bonded to the control pads on the control circuit board PCB in one-to-one correspondence. Meanwhile, to facilitate bonding of the control circuit board PCB and the second bonding portion BA2, the second bonding portion BA2 may include a second alignment mark Mark2, and the relationship between the second alignment mark Mark2 and the second pad PIN2 may be the same as the relationship between the first pad PIN1 and the first alignment mark Mark1, and details are not described here again.

The connecting portion CP may connect the first bonding portion BA1 and the second bonding portion BA2, and a first pad PIN1 is at least connected to a second pad PIN2 through the connection portion CP, which is not specifically limited here.

As shown in FIG. 8, the second conductive layer ML2 may at least partially overlap with the first bonding portion BA1, that is, there is an overlapping region between an orthographic projection of the second conductive layer ML2 on the substrate SU and an orthographic projection of the first conductive portion on the substrate SU. Meanwhile, the first conductive layer ML1 and the conductive layer may be connected to each other through the via hole HO penetrating through the substrate SU. The number of the via hole HO may be one or more, and the stability of the connection may be improved by using the plurality of via holes HO.

It should be noted that the drawings of the present disclosure only schematically show the position of the via hole HO, and do not constitute a limitation on the via hole HO, as long as the via hole HO can connect the first conductive layer MLI and the second conductive layer ML2.

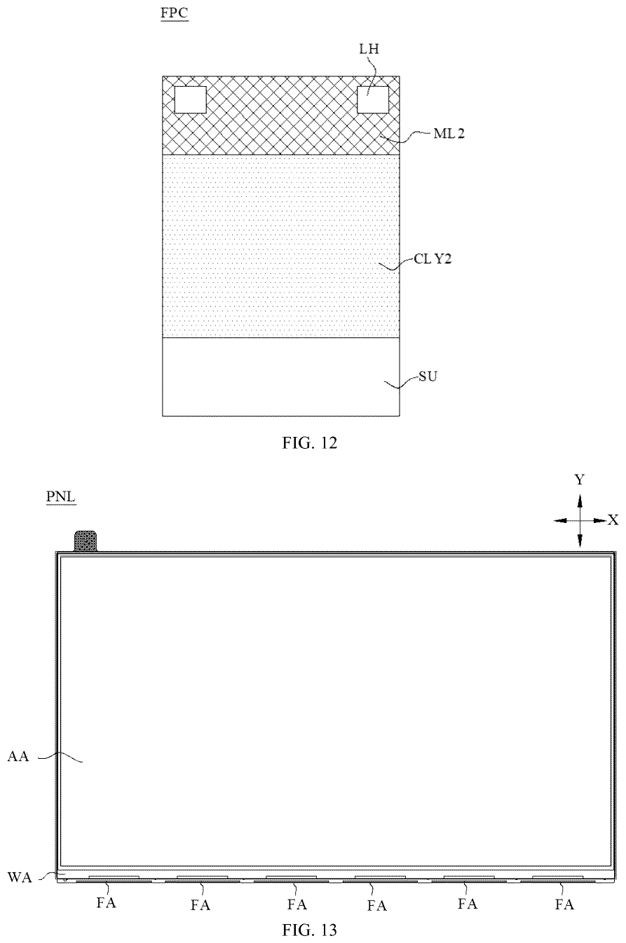

As shown in FIG. 12, in some embodiments of the present disclosure, the second conductive layer ML2 may only overlap with the first bonding portion BA1, and may not overlap with the connecting portion CP and the second bonding portion BA2. That is, the second conductive layer ML2 only covers a local region of the substrate SU, as long as the conductive protective layer TAP can be connected to the first conductive layer ML1, so that the flexible circuit board FPC may be of a single-layer conductive structure in a region corresponding to the connecting portion CP and the first conductive layer ML1, and may be of a multi-layer conductive structure only at the second conductive layer ML2. For the hard display panel, when bending the flexible circuit board FPC, the second conductive layer ML2 may not be bent, which is beneficial for improving the flexibility of the flexible circuit board FPC. For the flexible display panel, the second conductive layer ML2 may be bent along with the flexible circuit board FPC, or, may not participate in bending if the area is small.

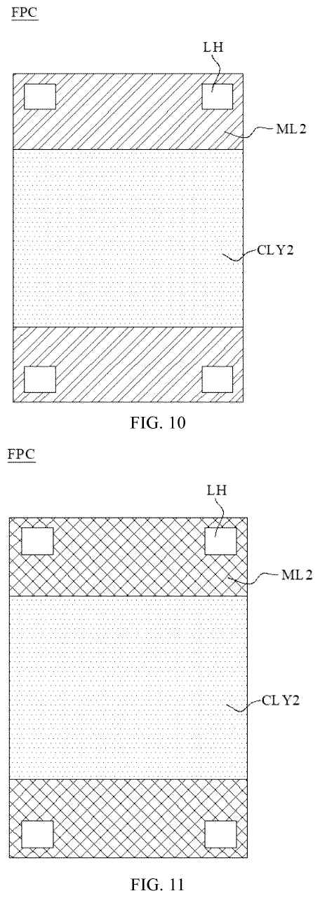

As shown in FIG. 10 and FIG. 11, in some other embodiments of the present disclosure, the second conductive layer ML2 may also overlap with the connecting portion CP and the second bonding portion BA2, may cover the entire substrate SU, and may also be bent when the flexible circuit board FPC is bent. Furthermore, as shown in FIG. 11, in order to facilitate bending of the flexible circuit board FPC, the second conductive layer ML2 may be of a mesh structure and has a plurality of mesh holes. The shape of the mesh hole is not specifically limited here, and it may be circular, rectangular, or the like, so that the flexibility of the flexible circuit board FPC is increased, which is convenient to bend.

In addition, the second conductive layer ML2 may also include a plurality of conductive units arranged at intervals, each conductive unit is connected to the first conductive layer ML1 through the via hole HO, and each conductive unit may conduct static electricity to the first conductive layer ML1.

Furthermore, as shown in FIG. 8, the flexible circuit board FPC may further include a first protective layer CLY1 and a second protective layer CLY2, where the first protective layer CLY1 may cover the first conductive layer ML1 and expose the first bonding portion BA1 and the second bonding portion BA2 for bonding. For example, the first protective layer CLY1 may be an entire continuous film layer covering the first conductive layer ML1, may be provided with a bonding hole exposing the first pad PIN1 at a position corresponding to each first pad PIN1, and may be provided with an opening at a position corresponding to the first alignment mark Mark1. Alternatively, the boundary of the first protection layer CLY1 may be aligned with the boundary of the first bonding portion BA1 and cover the connection portion CP to expose the first pad PIN1 and the first alignment mark Mark1, so that only the boundary of the first protection layer CLY1 needs to be controlled without an opening.

The second protective layer CLY2 may cover a partial region of the second conductive layer ML2 so as to be connected to the conductive portion. For example, the second protective layer CLY2 may be an entire continuous film layer covering the second conductive layer ML2, with an opening at a local region corresponding to the second conductive layer ML2. Alternatively, if the second conductive layer ML2 covers only a part of the substrate SU, the second protective layer CLY2 may cover the region of the substrate SU that is not covered by the second conductive layer ML2, and extend to the surface of the second conductive layer ML2 away from the substrate SU, but not completely cover the second conductive layer ML2. The purpose of exposing the second conductive layer ML2 may be achieved by controlling the extension boundary of the second protective layer CLY2 without a special opening. If the second conductive layer ML2 completely covers the substrate SU, it is only needed to control the area of the second protective layer CLY2 to be smaller than the area of the second conductive layer ML2, so that the purpose of exposing the second conductive layer ML2 can be achieved by controlling the extension boundary of the second protective layer CLY2 without a special opening.

The material of the first protective layer CLY1 and the second protective layer CLY2 may be a flexible material such as polyester and polyimide, or may be an insulating ink or the like, which is not specifically limited here.

In addition, as shown in FIG. 10 and FIG. 11, since the second conductive layer ML2 overlaps with the first bonding portion BA1, in order to avoid affecting the alignment due to that the identification of the first alignment mark Mark1 is affected by the blocking of the second conductive layer ML2, a light-transmitting hole LH penetrating through the second conductive layer ML2 may be formed in the second conductive layer ML2, and the light-transmitting hole LH overlaps with the first alignment mark Mark1, so that the first alignment mark Mark1 is identified through the light-transmitting hole LH, to implement alignment. For a plurality of first alignment marks Mark1, a plurality of light-transmitting holes LH may be provided in the second conductive layer ML2, and each light-transmitting hole LH is provided in an overlapping manner with each first alignment mark Mark1 in one-to-one correspondence. In some embodiments, a light-transmitting hole LH may also be provided in an overlapping manner with a plurality of first alignment marks Mark1, and the plurality of first alignment marks Mark1 may be identified through a light-transmitting hole LH. Correspondingly, if a second alignment mark Mark2 exists, a light-transmitting hole LH may also be provided at a position corresponding to the second alignment mark Mark2, so as to prevent the second alignment mark Mark2 from being blocked.

A light-transmitting hole LH overlapping with a first alignment mark Mark1 means that: the orthographic projection of the first alignment mark Mark1 on the substrate SU at least partially overlaps with the orthographic projection of the light-transmitting hole LH on the substrate SU, so that the first alignment mark Mark1 may be identified through the light-transmitting hole LH. Furthermore, the orthographic projection of the first alignment mark Mark1 on the substrate SU may be located within the orthographic projection of the light-transmitting hole LH on the substrate SU; that is, the boundary of the first alignment mark Mark1 is located within the boundary of the light-transmitting hole LH corresponding to the first alignment mark Mark1, so as to prevent the second conductive layer ML2 from blocking the first alignment mark Mark1.

In other embodiments of the present disclosure, in addition to the first conductive layer ML1 and the second conductive layer ML2, the flexible circuit board FPC may further include other conductive layers located between the first conductive layer ML1 and the second conductive layer ML2; that is, the flexible circuit board FPC may have more than three conductive layers, and two adjacent conductive layers may be connected to each other through via holes, so that the first conductive layer ML1 and the second conductive layer ML2 may be connected to each other. For example, the substrate may include two insulating layers distributed along a distribution direction of the first conductive layer ML1 and the second conductive layer ML2, a conductive layer is provided between the two insulating layers, and the conductive layer may be connected to the first conductive layer ML1 and the second conductive layer ML2 through via holes respectively, so as to achieve a transfer effect. In some embodiments, the conductive layer may also form a specific pattern to form a circuit, and the specific pattern is not specifically limited here.

As shown in FIG. 2 to FIG. 7, the conductive protection layer TAP may be used to cover the driving chip DIC, and the conductive protection layer TAP may be connected to the second conductive layer ML2, so that static electricity may be absorbed through the conductive protection layer TAP and conducted to the control circuit board PCB through the second conductive layer ML2 and the first conductive layer ML1, so as to finally realize grounding and avoid the influence of static electricity on the driving chip DIC.

As shown in FIG. 2 to FIG. 7, in some embodiments of the present disclosure, the conductive protective layer TAP may be of a bendable flexible structure, which may include an insulating layer IN and a conductor layer COL. The insulating layer IN may cover the driving chip DIC and be attached to the display panel PNL, and the material of the insulating layer IN may be polyester fiber cloth or other insulating fabric or other materials. The conductive layer COL may be stacked on a side of the insulating layer IN away from the display panel PNL, and the material of the conductive layer COL may be a metal or an alloy, such as a metal or alloy of nickel and copper, or may be a non-metallic conductive material such as graphite. A partial region of the conductor layer COL may extend to a side of the second conductive layer ML2 away from the substrate SU and be in contact with and connected to a partial region of the second conductive layer ML2, so that static electricity can be absorbed through the conductor layer COL and conducted to the second conductive layer ML2, where the insulating layer IN can prevent static electricity from being conducted to the driver chip.

Furthermore, as shown in FIG. 2 to FIG. 4, the display panel PNL is of a hard structure, and the flexible circuit board FPC needs to be bent to be bonded to the control circuit board PCB. The boundary of the conductive protection layer TAP may be located within the boundary of the display panel PNL. When the flexible circuit board FPC is bent, the conductive protection layer TAP may not be bent along with the flexible circuit, preventing the first bonding portion BA1 from be stripped from the panel bonding portion PA. In order to control the bending radius of the flexible circuit board FPC, the display module further includes a spacer layer SPA. Under that status that the flexible circuit board FPC is bent to the backlight side of the display panel PNL, the spacer layer SPA may be located between the supporting layer SCF and the flexible circuit board FPC, and abuts against the supporting layer SCF and the flexible circuit board FPC. Therefore, the distance between the supporting layer SCF and the flexible circuit board FPC may be limited through the spacer layer SPA, so that the bending radius of the flexible circuit board FPC may be controlled, and the problems of breakage or the like caused by too small bending radius of the flexible circuit board FPC may be avoided.

As shown in FIG. 5 to FIG. 7, the display panel PNL is a flexible display panel, a fan-out region FA needs to be bent, and then the display panel PNL is bonded to the control circuit board PCB. In order to control the bending radius of the fan-out region FA, and to enhance the reliability of deformation, in some embodiments of the present application, as shown in FIG. 5 to FIG. 7, the display module further includes a spacer layer SPA. Under the status that the fan-out region FA is bent to the backlight side of the display panel PNL, the spacer layer SPA may be located between the supporting layer SCF and the flexible circuit board FPC, and abut against the supporting layer SCF and the flexible circuit board FPC. Therefore, the distance between the supporting layer SCF and the flexible circuit board FPC may be limited through the spacer layer SPA, so that the bending radius of the fan-out region FA may be controlled, and the problems of breakage or the like caused by too small bending radius of the fan-out region FA may be avoided.

In addition, as shown in FIG. 13 and FIG. 14, in some embodiments of the present disclosure, the display panel PNL has a plurality of fan-out regions FA, and each fan-out region FA may be distributed at intervals along the row direction X. A driver chip (not shown) may be provided in each fan-out region FA. Each fan-out region FA may be bonded to a flexible circuit board FPC, and each flexible circuit board FPC may be bonded to the same control circuit board PCB. Meanwhile, each flexible circuit board FPC may be bent simultaneously, so that the control circuit board PCB is located on the backlight side of the display panel PNL. Each fan-out region FA may be simultaneously covered by the same conductive protection layer TAP, so that static electricity is shielded for each driving chip. In some embodiments, each fan-out region may also be covered by an independent conductive protection layer TAP, and each conductive protection layer TAP may be distributed at intervals along the distribution direction of the fan-out regions FA.

The present disclosure further provides a terminal device, which may be a mobile phone, a tablet computer, a wearable device (such as a smart bracelet, a watch), a notebook computer, a television, or another similar device having an image display function, which will not be listed one by one here. The terminal device of the present disclosure may include a control circuit board PCB and a display module.

The control circuit board PCB may be provided on the backlight side of the display panel PNL and may be in contact with the supporting layer SCF. For example, if the terminal device is a mobile phone, the control circuit board PCB may be a motherboard of the mobile phone. In some embodiments, the control circuit board PCB may also be an independent circuit board dedicated to controlling the display panel PNL.

As shown in FIG. 2 to FIG. 4, if the display panel PNL is a hard display panel, the flexible circuit board FPC of the display module may be bent to the backlight side of the display panel PNL, and the second bonding portion BA2 may be bonded to the control circuit board PCB, so that the display panel PNL may be controlled by the control circuit board PCB. In this case, the driving chip DIC is located on the light-emitting side of the display panel PNL.

As shown in FIG. 5 to FIG. 7, if the display panel PNL is a flexible display panel, the fan-out region FA of the display module may be bent to the backlight side of the display panel PNL, and the second bonding portion BA2 may be bonded to the control circuit board PCB, so that the display panel PNL may be controlled by the control circuit board PCB. In this case, the driving chip DIC may be located on the backlight side of the display panel PNL, but the solution of the present disclosure may still improve the effect of shielding static electricity in the environment. In some embodiments, as shown in FIG. 2 to FIG. 4, although the display panel PNL is a flexible display vertical panel, it may not be bent, and only the flexible circuit board FPC may be bent to the backlight side of the display panel PNL. In this case, the driving chip DIC may be located on the light-emitting side of the display panel PNL.

The light-emitting side of the display panel PNL is a side towards which the light-emitting direction of the light-emitting device faces, and the backlight side of the display panel PNL is a side opposite to the light-emitting direction. Taking the light-emitting device being of a top-emitting structure as an example, the light-emitting device emits light in a direction away from the driving backplane BP, the light-emitting side of the display panel PNL is a side of the light-emitting device layer OL away from the driving backplane BP, and the backlight side is a side of the driving backplane BP away from the light-emitting device layer OL.

For a specific structure of the terminal device of the present disclosure, reference may be made to the implementation of the display module above, and details are not described here again.

Other embodiments of the present disclosure will be apparent to those skilled in the art from consideration of the description and practice of the invention disclosed here. The present application is intended to cover any variations, uses, or adaptations of the present disclosure following the general principles of the present disclosure and including common knowledge and conventional technical means in the art not disclosed in the present disclosure. It is intended that the description and examples be considered as exemplary only.

1. A display module, comprising:
a display panel, provided with a display region and a peripheral region located outside the display region, wherein the peripheral region comprises a bendable fan-out region; the fan-out region is provided with a panel bonding portion, and the fan-out region is provided with a driving chip;
a flexible circuit board, comprising a first conductive layer, a second conductive layer, and a substrate separated between the first conductive layer and the second conductive layer; wherein the first conductive layer comprises a first bonding portion, a second bonding portion, and a connection portion connecting the first bonding portion and the second bonding portion; the second conductive layer is located on a side of the first conductive layer away from the display panel and at least partially overlaps with the first bonding portion; the first conductive layer and the second conductive layer are connected to each other through a via hole penetrating through the substrate; an end of the flexible circuit board is bonded to the panel bonding portion through the first bonding portion, and the second bonding portion is configured to be bonded to a control circuit board; and
a conductive protection layer, covering the driving chip and connected to the second conductive layer.

2. The display module according to claim 1, wherein the flexible circuit board further comprises a first protective layer and a second protective layer, the first protective layer covers the first conductive layer and exposes the first bonding portion and the second bonding portion, and the second protective layer covers a partial region of the second conductive layer.

3. The display module according to claim 1, wherein the first bonding portion comprises a first alignment mark and a plurality of first pads distributed at intervals, and the first pads are bonded to the panel bonding portion; the second conductive layer is provided with a light-transmitting hole, and the light-transmitting hole overlaps with the first alignment mark.

4. The display module according to claim 3, wherein a number of the first alignment mark and a number of the light-transmitting hole are both more than one, and a first pad is located between two adjacent first alignment marks; and the light-transmitting hole overlaps with the first alignment mark in one-to-one correspondence.

5. The display module according to claim 3, wherein a first alignment mark and a first pad are of an integrated structure.

6. The display module according to claim 1, wherein the second conductive layer further overlaps with the connecting portion and the second bonding portion.

7. The display module according to claim 6, wherein the second conductive layer is of a mesh structure.

8. The display module according to claim 1, wherein the second conductive layer only overlaps with the first bonding portion.

9. The display module according to claim 1, wherein materials of the first conductive layer and the second conductive layer are the same.

10. The display module according to claim 1, wherein a boundary of the conductive protection layer is located within a boundary of the display panel.

11. The display module according to claim 1, wherein the conductive protective layer comprises an insulating layer and a conductor layer stacked along a direction away from the display panel, the insulating layer covers the driving chip and is attached to the display panel; a partial region of the conductor layer extends to a side of the second conductive layer away from the substrate and is connected to a partial region of the second conductive layer.

12. The display module according to claim 1, wherein the display panel comprises:
a driving backplane, comprising the fan-out region and a pixel circuit located within the display region;
a light-emitting device, provided on a side of the driving backplane and located in the display region;
an encapsulation layer, covering the light-emitting device and exposing the driving chip and the panel bonding portion;
a touch layer, provided on a side of the encapsulation layer away from the driving backplane;
an anti-reflection layer, provided on a side of the touch layer away from the driving backplane; and
a transparent cover plate, provided on a side of the anti-reflection layer away from the driving backplane, wherein a boundary of the driving backplane is located within a boundary of the transparent cover plate.

13. The display module according to claim 12, wherein the driving backplane comprises a plurality of data lines extending along a column direction and distributed along a row direction, and a data line is connected to at least one column of pixel circuits; and, at least a part of the data lines are connected to the driving chip.

14. The display module according to claim 1, wherein the display panel further comprises:
a supporting layer, provided on a side of the driving backplane away from the light-emitting device, and comprising an adhesive layer, a buffer layer, and a metal layer sequentially stacked along a direction away from the driving backplane.

15. A terminal device, comprising:
a control circuit board, provided on a backlight side of the display panel; and
a display module, comprising:
a display panel, provided with a display region and a peripheral region located outside the display region, where the peripheral region comprises a bendable fan-out region; the fan-out region is provided with a panel bonding portion, and the fan-out region is provided with a driving chip;
a flexible circuit board, comprising a first conductive layer, a second conductive layer, and a substrate separated between the first conductive layer and the second conductive layer; where the first conductive layer comprises a first bonding portion, a second bonding portion, and a connection portion connecting the first bonding portion and the second bonding portion; the second conductive layer is located on a side of the first conductive layer away from the display panel and at least partially overlaps with the first bonding portion; the first conductive layer and the second conductive layer are connected to each other through a via hole penetrating through the substrate; an end of the flexible circuit board is bonded to the panel bonding portion through the first bonding portion, and the second bonding portion is configured to be bonded to a control circuit board; and
a conductive protection layer, covering the driving chip and connected to the second conductive layer;
wherein the second bonding portion is connected to the control circuit board.

16. The terminal device according to claim 15, wherein the flexible circuit board further comprises a first protective layer and a second protective layer, the first protective layer covers the first conductive layer and exposes the first bonding portion and the second bonding portion, and the second protective layer covers a partial region of the second conductive layer.

17. The terminal device according to claim 15, wherein the first bonding portion comprises a first alignment mark and a plurality of first pads distributed at intervals, and the first pads are bonded to the panel bonding portion; the second conductive layer is provided with a light-transmitting hole, and the light-transmitting hole overlaps with the first alignment mark.

18. The terminal device according to claim 15, wherein the conductive protective layer comprises an insulating layer and a conductor layer stacked along a direction away from the display panel, the insulating layer covers the driving chip and is attached to the display panel; a partial region of the conductor layer extends to a side of the second conductive layer away from the substrate and is connected to a partial region of the second conductive layer.

19. The terminal device according to claim 15, wherein the display panel comprises:
a driving backplane, comprising the fan-out region and a pixel circuit located within the display region;
a light-emitting device, provided on a side of the driving backplane and located in the display region;
an encapsulation layer, covering the light-emitting device and exposing the driving chip and the panel bonding portion;
a touch layer, provided on a side of the encapsulation layer away from the driving backplane;
an anti-reflection layer, provided on a side of the touch layer away from the driving backplane; and
a transparent cover plate, provided on a side of the anti-reflection layer away from the driving backplane, wherein a boundary of the driving backplane is located within a boundary of the transparent cover plate.

20. The terminal device according to claim 15, wherein the display panel further comprises:
a supporting layer, provided on a side of the driving backplane away from the light-emitting device, and comprising an adhesive layer, a buffer layer, and a metal layer sequentially stacked along a direction away from the driving backplane.
